(19) United States
(12) Patent Application Publication
(10) Pub. No.: US 2019/0115920 A1
(43) Pub. Date: Apr. 18, 2019

(54) Configurable Computing-Array Package Implementing Complex Math Functions

(71) Applicant: Guobiao ZHANG, Corvallis, OR (US)

(72) Inventor: Guobiao ZHANG, Corvallis, OR (US)

(73) Assignee: HangZhou HaiCun Information Technology Co., Ltd., HangZhou (CN)

(21) Appl. No.: 16/199,204

(22) Filed: Nov. 25, 2018

Related U.S. Application Data
(63) Continuation of application No. 15/793,968, filed on Oct. 25, 2017.
Application No. 15/793,968 is a continuation-in-part of application No. 15/450,049, filed on Mar. 6, 2017, now Pat. No. 9,838,021.
Application No. 15/450,049 is a continuation-in-part of application No. 15/450,017, filed on Mar. 5, 2017, now Pat. No. 9,948,306.

(30) Foreign Application Priority Data
Mar. 5, 2016 (CN) 201610125227.8
May 10, 2016 (CN) 201610307102.7
Oct. 19, 2017 (CN) 201710996864.7
Oct. 20, 2017 (CN) 201710980817.3
Oct. 20, 2017 (CN) 201710998652.2

(51) Int. Cl. H03K 19/177; G11C 5/02; H03K 19/173; G11C 29/02; H01L 27/105

(52) U.S. Cl. CPC H03K 19/1776; H03K 19/17728; G11C 5/02; H01L 27/1052; H03K 19/1737; G11C 29/028; H03K 19/17744

(57) ABSTRACT

A preferred configurable computing-array package comprises a configurable logic die including an array of configurable logic elements and a configurable computing die including an array of configurable computing elements. Each configurable logic element is capable of realizing any one of a plurality of logic functions in a logic library. Each configurable computing element stores at least a look-up table (LUT) for a math function, which includes more operations than the arithmetic operations included in the logic library.

### CROSS-REFERENCE TO RELATED APPLICATIONS

This application is a continuation of U.S. patent application Ser. No. 15/793,968, filed Oct. 25, 2017, which is a continuation-in-part of U.S. patent application Ser. No. 15/450,049, filed Mar. 6, 2017, now U.S. Pat. No. 9,838,021, issued Dec. 5, 2017, which is a continuation-in-part of U.S. patent application Ser. No. 15/450,017, filed Mar. 5, 2017, now U.S. Pat. No. 9,948,306, issued Apr. 17, 2018.

These applications claim priorities from Chinese Patent Application No. 201610125227.8, filed Mar. 5, 2016; Chinese Patent Application No. 201610307102.7, filed May 10, 2016; Chinese Patent Application No. 201710996864.7, filed Oct. 19, 2017; Chinese Patent Application No. 201710998652.2, filed Oct. 20, 2017; Chinese Patent Application No. 201710980817.3, filed Oct. 20, 2017, in the State Intellectual Property Office of the People's Republic of China (CN), the disclosure of which are incorporated herein by reference in their entireties.

### BACKGROUND

### 1. Technical Field of the Invention

The present invention relates to the field of integrated circuit, and more particularly to configurable gate array.

### 2. Prior Art

A configurable gate array is a semi-custom integrated circuit designed to be configured by a customer after manufacturing. U.S. Pat. No. 4,870,302 issued to Freeman on Sep. 26, 1989 (hereinafter referred to as Freeman) discloses a configurable gate array. It contains an array of configurable logic elements (also known as configurable logic blocks) and a hierarchy of configurable interconnects (also known as programmable interconnects) that allow the configurable logic elements to be wired together. Each configurable logic element in the array is in itself capable of realizing any one of a plurality of logic functions in a logic library (e.g. shift, logic NOT, logic AND, logic OR, logic NOR, logic NAND, logic XOR, arithmetic addition “+”, arithmetic subtraction “−”, etc.) depending upon a first configuration signal. Each configurable interconnect can selectively couple or de-couple interconnect lines depending upon a second configuration signal.

Complex math functions are widely used in various applications. A complex math function has multiple independent variables and can be expressed as a combination of basic math functions. On the other hand, a basic function has a single or few independent variables. Exemplary basic functions include transcendental functions, such as exponential function (exp), logarithmic function (log), trigonometric functions (sin, cos, tan, a tan) and others. To meet the speed requirements, many high-performance applications require that these complex math functions be implemented in hardware. In conventional configurable gate arrays, complex math functions are implemented in fixed computing elements, which are portions of hard blocks and not configurable, i.e. the circuits implementing these complex math functions are fixedly connected and are not subject to change by programming. Apparently, fixed computing elements would limit further applications of the configurable gate array. To overcome this difficulty, the present invention expands the original concept of the configurable gate array by making the fixed computing elements configurable. In other words, besides configurable logic elements, the configurable gate array comprises configurable computing elements, which can realize any one of a plurality of math functions. Each of these math functions include more operations than the arithmetic operations included in the logic library of Freeman (i.e. arithmetic addition “+” and arithmetic subtraction “−”).

### Objects and Advantages

It is a principle object of the present invention to extend the applications of a configurable gate array to the field of complex math computation.

It is a further object of the present invention to provide a configurable computing array where not only logic functions can be customized, but also math functions.

It is a further object of the present invention to provide a configurable computing array with a small size and a fast computational speed.

It is a further object of the present invention to provide a configurable computing array with a short time-to-market and good manufacturability.

In accordance with these and other objects of the present invention, the present invention discloses a configurable computing-array package.

### SUMMARY OF THE INVENTION

The present invention discloses a configurable computing-array package. It comprises a configurable computing die comprising an array of configurable computing elements and a configurable logic die comprising an array of configurable logic elements. The configurable computing-array package further comprises a plurality of configurable interconnects, which are located on the configurable computing die and/or the configurable logic die. Each configurable computing element comprises at least a writable-memory array, which is electrically programmable and can be loaded with a look-up table (LUT) for a math function. Being electrically programmable, the math functions that can be realized by a writable-memory array are essentially boundless.

The usage cycle of the configurable computing element comprises two stages: a configuration stage and a computation stage. In the configuration stage, the LUT for a desired math function is loaded into the writable-memory array. In the computation stage, a selected portion of the LUT for the desired math function is read out from the writable-memory array. For a re-programmable memory array, a configurable computing element can be re-configured to realize different math functions at different time.

Besides configurable computing elements, the preferred configurable computing-array package further comprises configurable logic elements and configurable interconnects. During operation, a complex math function is first decomposed into a combination of basic math functions. Each basic math function is realized by programming the associated configurable computing element. The complex math function is then realized by programming the appropriate configurable logic elements and configurable interconnects.

Accordingly, the present invention discloses a configurable computing-array package, comprising: a configurable computing die comprising at least a configurable computing element for storing at least a portion of a look-up table (LUT) for a math function; a configurable logic die comprising at least a configurable logic element for selectively realizing a logic function from a logic library; a plurality of inter-die connections for coupling said configurable computing die and said configurable logic die; wherein said configurable computing-array package realizes a math function by programming said configurable computing element and said configurable logic element.

The present invention further discloses another configurable computing-array package, comprising: a configurable computing die comprising at least a configurable computing element for storing at least a portion of a look-up table (LUT) for a math function; a configurable logic die comprising at least a configurable logic element for selectively realizing a logic function from a logic library; at least a configurable interconnect for selectively realizing an interconnect from an interconnect library; a plurality of inter-die connections for coupling said configurable computing die and said configurable logic die; wherein said configurable computing-array package realizes a math function by programming said configurable computing element, said configurable logic element and said configurable interconnect.

### BRIEF DESCRIPTION OF THE DRAWINGS

FIG. 1 discloses a symbol for a preferred configurable computing element;

FIG. 2 is a layout view of the preferred configurable computing element;

FIG. 3 discloses two usage cycles of a preferred re-configurable computing element;

FIG. 4A shows an interconnect library supported by a preferred configurable interconnect; FIG. 4B shows a logic library supported by a preferred configurable logic element;

FIG. 5 is a circuit block diagram of a first preferred configurable computing-array package;

FIG. 6 shows an instantiation of the first preferred configurable computing-array package;

FIG. 7 is a circuit block diagram of a second preferred configurable computing-array package;

FIGS. 8A-8B show two instantiations of the second preferred configurable computing-array package;

FIG. 9 is a perspective view of a preferred configurable computing-array package.

FIGS. 10A-10C are cross-sectional views of three preferred configurable computing-array packages.

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments. In the present invention, the terms “write”, “program” and “configure” are used interchangeably. The symbol “/” means a relationship of “and” or “or”.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

Referring now to FIG. 1, a symbol for a preferred configurable computing element 100 is shown. The input port IN includes input data 115, the output port OUT includes output data 135, and the configuration port CFG includes at least a configuration signal 125. When the configuration signal 125 is “write”, the look-up table (LUT) for a desired math function is loaded into the configurable computing element 100; when the configuration signal 125 is “read”, the functional/derivative/other value of the desired math function is read out from the LUT.

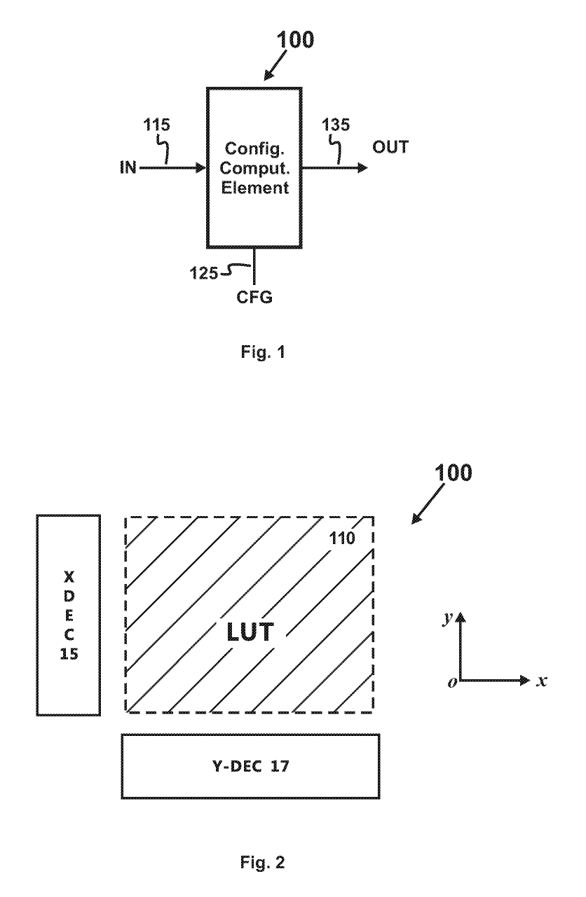

FIG. 2 is a layout view of the preferred configurable computing element 100. The LUT is stored in at least a writable-memory array 110. The configurable computing element 100 further includes the X decoder 15 and Y decoder (including read-out circuit) 17 of the writable-memory array 110. The writable-memory array 110 could be a RAM array or a ROM array. Exemplary RAM includes SRAM, DRAM, etc. On the other hand, exemplary ROM includes OTP (one-time-programmable) and MTP (multiple-time-programmable, including re-programmable), etc. Among them, the MTP further includes EPROM, EEPROM, flash memory, 3-D memory including 3D-NAND, 3D-XPoint and others, etc.

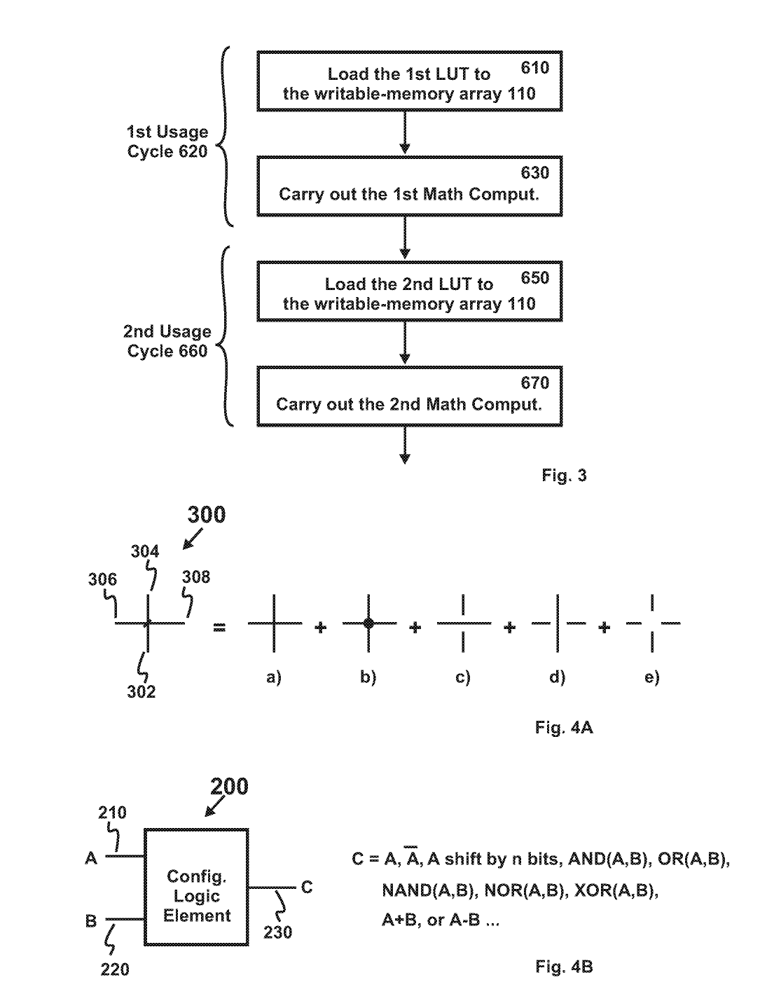

Referring now to FIG. 3, two usage cycles 620, 660 of a preferred re-configurable computing element 100 are shown. For the re-configurable computing element 100, the writable-memory array 110 is re-programmable. The first usage cycle 620 includes two stages: a configuration stage 610 and a computation stage 630. In the configuration stage 610, the LUT for a first desired math function is loaded into the writable-memory array 110. In the computation stage 630, a selected portion of the LUT for the first desired math function is read out from the writable-memory array 110. Being re-programmable, the re-configurable computing element 100 can realize different math functions during different usage cycles 620, 660. During the second usage cycle 660 (including two stages 650, 670), the LUT for a second desired math function is loaded and later read out. The re-configurable computing element 100 is particularly suitable for single-instruction-multiple-data (SIMD)-type of data processing. Once the LUTs are loaded into the writable-memory arrays 110 in the configuration stage, a large amount of data can be fed into the re-configurable computing element 100 and processed at high speed. SIMD has many applications, e.g. vector processing in image processing, massively parallel processing in scientific computing.

Referring now to FIGS. 4A-4B, an interconnect library and a logic library are shown. FIG. 4A shows the interconnect library supported by a preferred configurable interconnect 300. An interconnect library is a collection of all interconnects supported by a configurable interconnect. This interconnect library includes the followings: a) the interconnects 302/304 are coupled, the interconnects 306/308 are coupled, but 302/304 are not connected with 306/308; b) the interconnects 302/304/306/308 are all coupled; c) the interconnects 306/308 are coupled, but the interconnects 302, 304 are not coupled, neither are 302, 304 connected with 306/308; d) the interconnects 302/304 are coupled, but the interconnects 306, 308 are not coupled, neither are 306, 308 connected with 302/304; e) interconnects 302, 304, 306, 308 are not coupled at all. As used herein, the symbol “/” between two interconnects means that these two interconnects are coupled, while the symbol “,” between two interconnects means that these two interconnects are not coupled. More details on the configurable interconnects are disclosed in Freeman.

FIG. 4B shows the logic library supported by a preferred configurable logic element 200. A logic library is a collection of all logic functions supported by a configurable logic element. In this preferred embodiment, the inputs A and B include input data 210, 200, and the output C includes the output data 230. The logic library includes the following logic functions: C=A, NOT A, A shift by n bits, AND(A,B), OR(A,B), NAND(A,B), NOR(A,B), XOR(A,B), A+B, A-B. To facilitate pipelining, the configurable logic element 200 may comprise sequential logic such as flip-flops and registers. More details on the configurable logic elements are disclosed in Freeman.

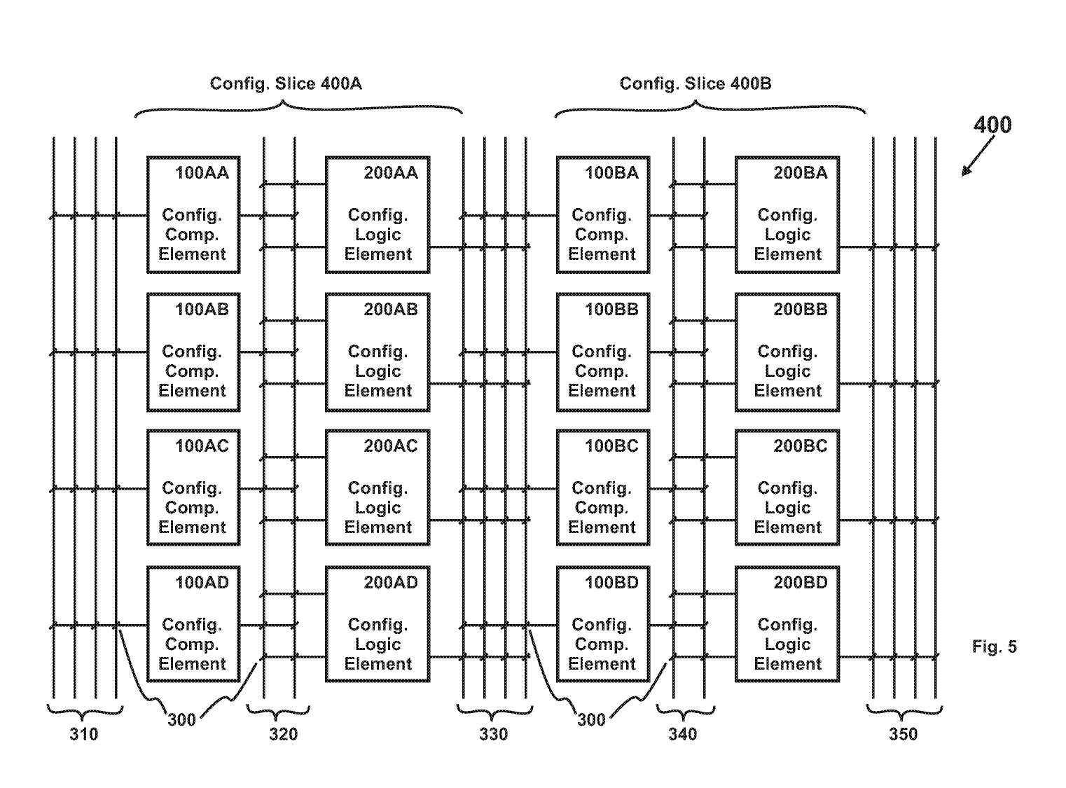

Referring now to FIG. 5, a first preferred configurable computing-array package 400 is disclosed. It comprises first and second configurable slices 400A, 400B. Each configurable slice (e.g. 400A) comprises a first array of configurable computing elements (e.g. 100AA-100AD) and a second array of configurable logic elements (e.g. 200AA-200AD). A configurable channel 320 is placed between the first array of configurable computing elements (e.g. 100AA-100AD) and the second array of configurable logic elements (e.g. 200AA-200AD). The configurable channels 310, 330, 350 are also placed between different configurable slices 300A, 300B. The configurable channels 310-350 comprise an array of configurable interconnects 300. For those skilled in the art, besides configurable channels, sea-of-gates may also be used.

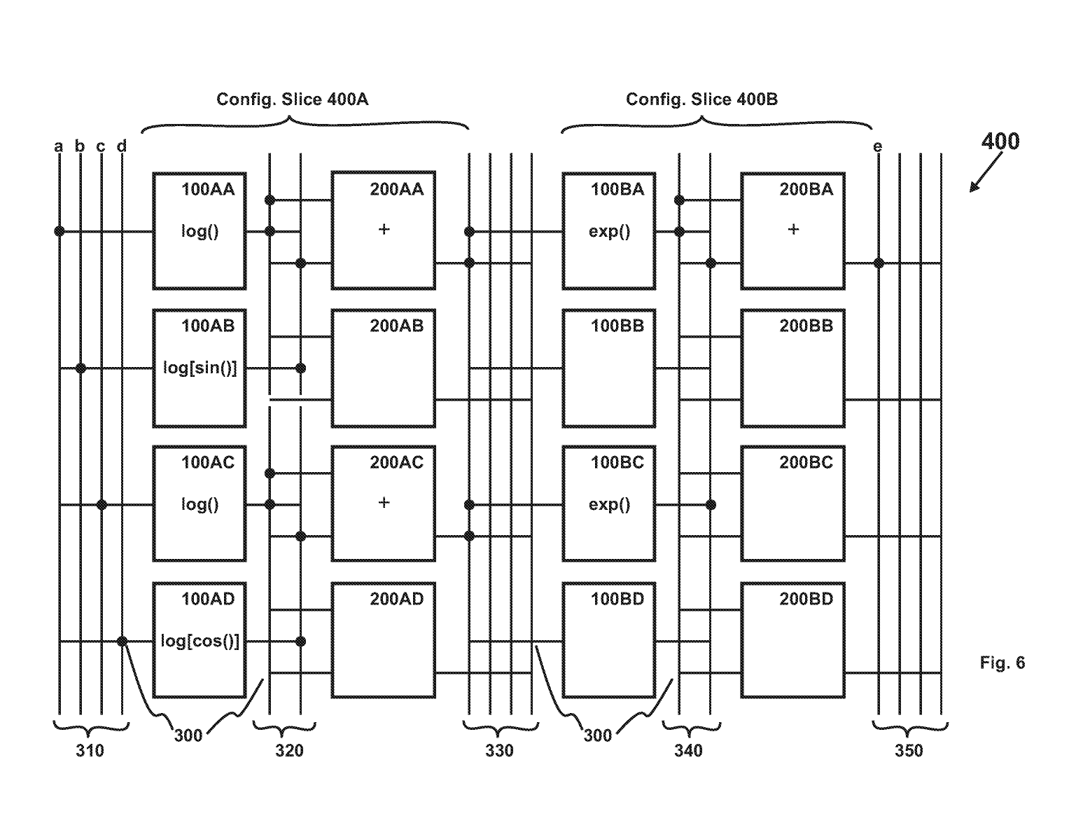

FIG. 6 discloses an instantiation of the first preferred configurable computing-array package implementing a complex math function e=a·sin(b)+c·cos(d). The configurable interconnects 300 in the configurable channel 310-350 use the same convention as FIG. 4A: the interconnects with dots mean that the interconnects are connected; the interconnects without dots mean that the interconnects are not connected; a broken interconnect means that two broken sections are disconnected. In this preferred implementation, the configurable computing element 100AA is configured to realize the function log( ) whose result log(a) is sent to a first input of the configurable logic element 200A. The configurable computing element 100AB is configured to realize the function log[sin( )], whose result log[sin(b)] is sent to a second input of the configurable logic element 200A. The configurable logic element 200A is configured to realize arithmetic addition “+”, whose result log(a)+log[sin(b)] is sent the configurable computing element 100BA. The configurable computing element 100BA is configured to realize the function exp( ) whose result exp{log(a)+log[sin(b)]}=a·sin(b) is sent to a first input of the configurable logic element 200BA. Similarly, through proper configurations, the results of the configurable computing elements 100AC, 100AD, the configurable logic elements 200AC, and the configurable computing element 100BC can be sent to a second input of the configurable logic element 200BA. The configurable logic element 200BA is configured to realize arithmetic addition “+”, whose result a·sin(b)+c·cos(d) is sent to the output e. Apparently, by changing its configuration, the configurable computing-array package 400 can realize other complex math functions.

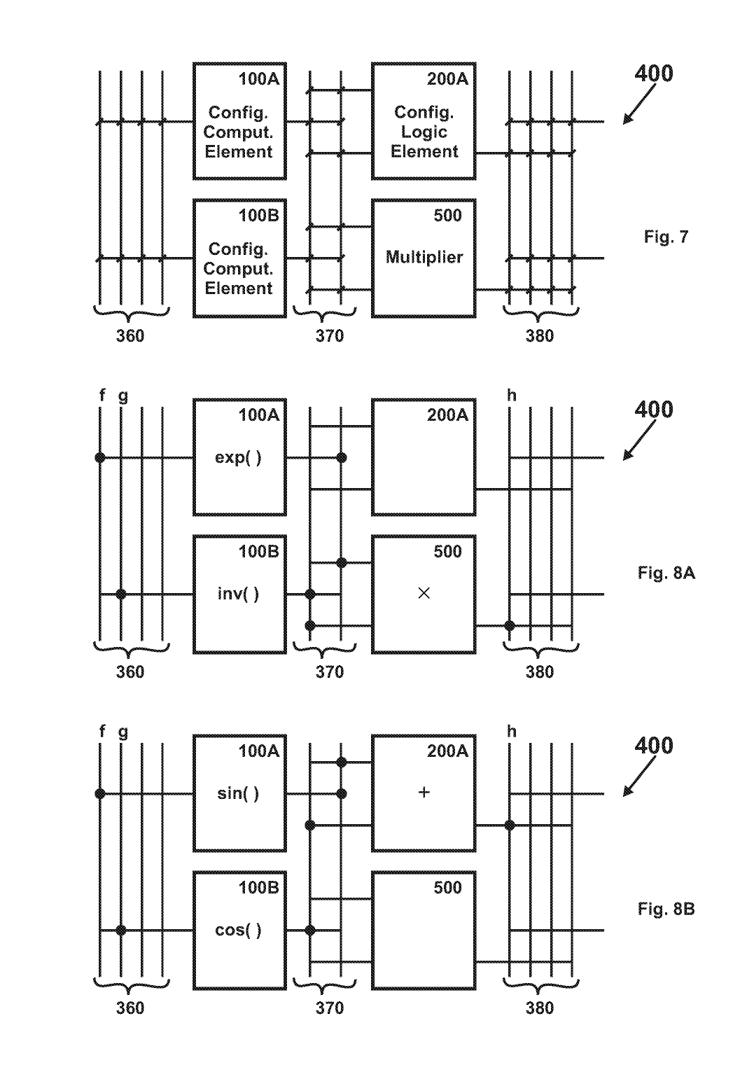

Referring now to FIG. 7, a second preferred configurable computing-array package 400 is shown. Besides configurable computing elements 100A, 100B and configurable logic element 200A, this preferred embodiment further comprises a multiplier 500. The configurable channels 360-380 comprise a plurality of configurable interconnects. With the addition of the multiplier 500, the preferred configurable computing-array package 400 can realize more math functions and its computational power will become more powerful.

FIGS. 8A-8B disclose two instantiations of the second preferred configurable computing-array package 400. In the instantiation of FIG. 8A, the configurable computing element 100A is configured to realize the function exp(f), while the configurable computing element 100B is configured to realize the function inv(g). The configurable channel 370 is configured in such a way that the outputs of 100A, 100B are fed into the multiplier 500. The final output is then h=exp(f)*inv(g). On the other hand, in the instantiation of FIG. 8B, the configurable computing element 100A is configured to realize the function sin(f), while the configurable computing element 100B is configured to realize the function cos(g). The configurable channel 370 is configured in such a way that the outputs of 100A, 100B are fed into the configurable logic element 200A, which is configured to realize arithmetic addition. The final output is then h=sin(f)+cos(g).

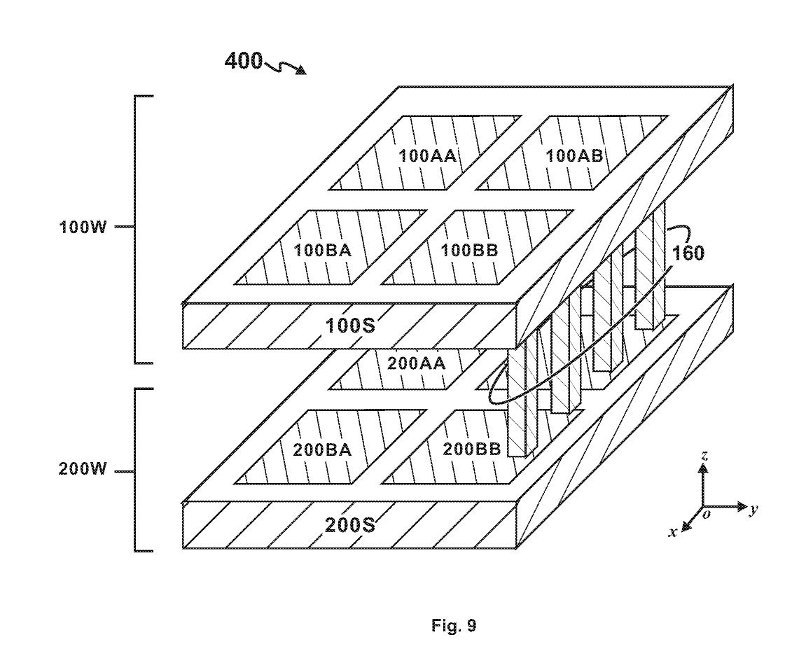

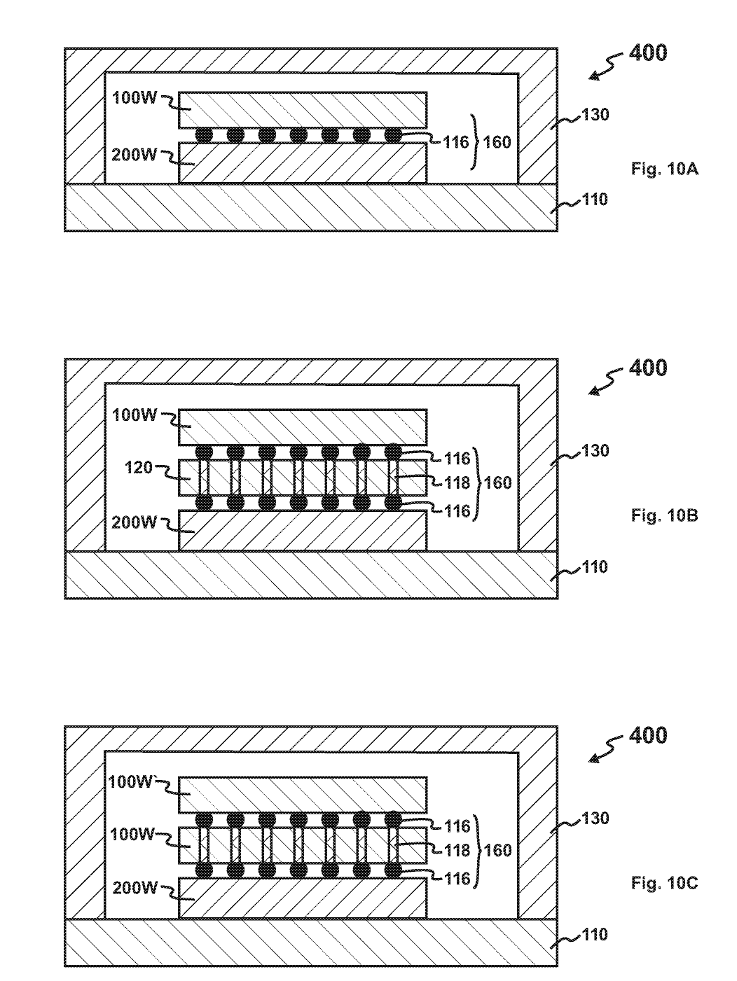

Referring now to FIG. 9, a perspective view of a preferred configurable computing-array package 400 is disclosed. The preferred configurable computing-array package 400 comprises a configurable computing die 100W and a configurable logic die 200W. The configurable computing die 100W is formed on a first semiconductor substrate 1005 and comprises at least an array of configurable computing elements 100AA-100BB. Each configurable computing element 100 comprises a writable-memory array 110 for storing at least a portion of an LUT for a math function. On the other hand, the configurable logic die 200W is formed on a second semiconductor substrate 200S and comprises at least an array of configurable logic elements 200AA-200BB. Each configurable logic element 200 selectively realizes a logic function from a logic library. The configurable computing die 100W and the configurable logic die 200W are located in a same package. In this preferred embodiment, the configurable computing die 100W is stacked on/above the configurable logic die 200W. As will be shown in FIGS. 10A-10C, other stacking configurations are possible. In addition, the configurable computing die 100W and the configurable logic die 200W are communicatively coupled by a plurality of inter-die connections 160. Exemplary inter-die connections include micro-bumps and through-silicon-vias (TSV). The preferred configurable computing-array package 400 further comprises a plurality of configurable interconnects, each of which selectively realizes an interconnect from an interconnect library. The configurable interconnects could be located on the configurable computing die 100W and/or the configurable logic die 200W.

Referring now to FIGS. 10A-10C, the cross-sectional views of three preferred configurable computing-array package 400 are shown. These preferred embodiments are located in multi-chip packages (MCP). Among them, the configurable computing-array package 400 in FIG. 10A comprises two separate dice: a configurable computing die 100W and a configurable logic die 200W. The dice 100W, 200W are stacked on the package substrate 110 and located in a same package 130. Micro-bumps 116 act as the inter-die connections 160 and provide electrical coupling between the dice 100, 200. In this preferred embodiment, the configurable computing die 100W is stacked on the configurable logic die 200W; the configurable computing die 100W is flipped and then bonded face-to-face with the configurable logic die 200W. Alternatively, the configurable logic die 200W could be stacked on/above the configurable computing die 100W. Either die does not have to be flipped.

The configurable computing-array package 400 in FIG. 1013 comprises a configurable computing die 100W, an interposer 120 and a configurable logic die 200W. The interposer 120 comprise a plurality of through-silicon vias (TSV) 118. The TSVs 118 provide electrical couplings between the configurable computing die 100W and the configurable logic die 200W. They offer more freedom in design and facilitate heat dissipation. In this preferred embodiment, the TSVs 118 and the micro-bumps 116 collectively form the inter-die connections 160.

The configurable computing-array package 400 in FIG. 10C comprises at least two configurable computing dice 100W, 100W′ and a configurable logic die 200W. These dice 100W, 100W, 200W are separate dice and located in a same package 130. Among them, the configurable computing die 100W′ is stacked on the configurable computing die 100W, while the configurable computing die 100W is stacked on the configurable logic die 200W. The dice 100W, 100W, 200W are electrically coupled through the TSVs 118 and the micro-bumps 116. Apparently, the LUT in FIG. 10C has a large capacity than that in FIG. 10A. Similarly, the TSVs 118 and the micro-bumps 116 collectively form the inter-die connections 160.

Because the configurable computing die 100W and the configurable logic die 200W are located in a same package, this type of integration is referred to as 2.5-D integration. The 2.5-D integration excels the conventional 2-D integration in many aspects. Firstly of all, the footprint of a conventional 2D-integrated configurable computing array is roughly equal to the sum of those of the configurable computing elements, the configurable logic elements and the configurable interconnects. On the other hand, because the 2.5-D integration moves the configurable computing elements from aside to above, the configurable computing-array package 400 becomes smaller and computationally more powerful. Secondly, because they are physically close and coupled by a large number of inter-die connections 160, the configurable computing die 100W and the configurable logic die 200W have a larger communication bandwidth than the conventional 2D-integrated configurable computing array. Thirdly, the 2.5-D integration benefits manufacturing process. Because the configurable computing die 100W and the configurable logic die 200W are separate dice, the memory transistors in the configurable computing die 100W and the logic transistors in the configurable logic die 200W are formed on separate semiconductor substrates. Consequently, their manufacturing processes can be individually optimized.

The preferred embodiments of the present invention are field-programmable computing-array (FPCA) package. For an FPCA package, all manufacturing processes of the configurable computing die and the configurable logic die are finished in factory. The function of the FPCA package can be electrically defined in the field of use. The concept of FPCA package can be extended to mask-programmed computing-array (MPCA) package. For a MPCA package, the wafers containing the configurable computing elements and/or the wafer containing the configurable logic elements are prefabricated and stockpiled. However, certain interconnects on these wafers are not fabricated until the function of the MPCA package is finally defined.

While illustrative embodiments have been shown and described, it would be apparent to those skilled in the art that many more modifications than that have been mentioned above are possible without departing from the inventive concepts set forth therein. The invention, therefore, is not to be limited except in the spirit of the appended claims.

What is claimed is:

1. A configurable computing-array package, comprising:
a configurable logic die comprising at least an array of configurable logic elements including a configurable logic element, wherein said configurable logic element selectively realizes a logic function from a logic library;
a configurable computing die comprising at least an array of configurable computing elements including first and second configurable computing elements, wherein said first configurable computing element comprises at least a first memory for storing a first look-up table (LUT) for a first math function; and, said second configurable computing element comprises at least a second memory for storing a second LUT for a second math function;
a plurality of inter-die connections for communicatively coupling said configurable logic die and said configurable computing die;
whereby said configurable computing-array package realizes a third math function by programming said configurable logic elements and said configurable computing elements, wherein said third math function is a combination of at least said first and second math functions;
wherein each of said first, second and third math functions includes more operations than arithmetic operations included in said logic library.

2. The configurable computing-array package according to claim 1, further comprising at least a configurable interconnect for selectively coupling said configurable computing element and said configurable logic element.

3. The configurable computing-array package according to claim 2, wherein said configurable interconnect is located on said configurable computing die.

4. The configurable computing-array package according to claim 2, wherein said configurable interconnect is located on said configurable logic die.

5. The configurable computing-array package according to claim 1, wherein said configurable computing element comprises a writable-memory array.

6. The configurable computing-array package according to claim 5, wherein said writable-memory array is re-programmable; and, said configurable computing element can be re-configured to realize different non-arithmetic functions.

7. The configurable computing-array package according to claim 1, wherein said inter-die connections are micro-bumps.

8. The configurable computing-array package according to claim 1, wherein said inter-die connections are through-silicon-vias (TSV).

9. The configurable computing-array package according to claim 1, further comprising at least one multiplier.

10. The configurable computing-array package according to claim 1, wherein said configurable computing die and said configurable logic die are vertically stacked.

11. A configurable computing-array package, comprising:
a configurable logic die comprising at least an array of configurable logic elements including a configurable logic element, wherein said configurable logic element selectively realizes a logic function from a logic library;
a configurable computing die comprising at least an array of configurable computing elements including first and second configurable computing elements, wherein said first configurable computing element comprises at least a first memory for storing a first look-up table (LUT) for a first math function; and, said second configurable computing element comprises at least a second memory for storing a second LUT for a second math function;
a plurality of configurable interconnects including a configurable interconnect, wherein said configurable interconnect selectively realizes an interconnect from an interconnect library;
a plurality of inter-die connections for communicatively coupling said configurable logic die and said configurable computing die;
whereby said configurable computing-array package realizes a third math function by programming said configurable logic elements and said configurable computing elements, wherein said third math function is a combination of at least said first and second math functions;
wherein each of said first, second and third math functions includes more operations than arithmetic operations included in said logic library.

12. The configurable computing-array package according to claim 11, wherein said configurable interconnects selectively couple said configurable computing elements and said configurable logic elements.

13. The configurable computing-array package according to claim 12, wherein said configurable interconnect is located on said configurable computing die.

14. The configurable computing-array package according to claim 12, wherein said configurable interconnect is located on said configurable logic die.

15. The configurable computing-array package according to claim 10, wherein said configurable computing element comprises at least a writable-memory array.

16. The configurable computing-array package according to claim 15, wherein said writable-memory array is a RAM array or a ROM array.

17. The configurable computing-array package according to claim 11, wherein said inter-die connections are micro-bumps.

18. The configurable computing-array package according to claim 11, wherein said inter-die connections are through-silicon-vias (TSV).

19. The configurable computing-array package according to claim 11, further comprising at least one multiplier.

20. The configurable computing-array package according to claim 11, wherein said configurable computing die and said configurable logic die are vertically stacked.
